(19) United States
(12) Patent Application Publication
(10) Pub. No.: US 2004/0169592 A1
(43) Pub. Date: Sep. 2, 2004

(54) Electric mechanism comprising a navigation key

(76) Inventor: Nicolae Valeriu Patachi, Le Mans (FR)

Correspondence Address: Corporate Patent Counsel, Philips Electronics North America Corporation, P O Box 3001, Briarcliff Manor, NY, 10510, US

(21) Appl. No.: 10/482,880

(22) PCT Filed: Jul. 4, 2002
(86) PCT No.: PCT/IB02/02838

(30) Foreign Application Priority Data
Jul. 10, 2001 (FR) 01/09168

(51) Int. Cl. H03M 11/00; H03K 17/94

(52) U.S. Cl. 341/22

(57) ABSTRACT

This electric mechanism comprises a keyboard (12) which includes a navigation key (15) showing on one side a surface for the user to depress and on the other side various contact points (21, 22, 23 and 24). To avoid various contacts being activated when this key is pressed, a configuration of ribs (30) is provided to separate said contact points and thus avoid multiple contacts. Application to cellular radiotelephones.

The invention relates to an electric mechanism comprising a keyboard which includes at least one navigation key, showing on one side a surface for the user to depress and on the other side various contact points.

The invention finds interesting applications when notably the mechanism is a radiotelephone and it is convenient to make various operation menus scroll on its screen by acting on this navigation key.

A mechanism is of the type known from European patent EP 0 581 583. In this document is proposed to have a protuberance in the center of the navigation key which should provide better comfort to the user. On the other hand, no indication is given about the fact that during a depression in one direction not several contacts are activated which thwarts the scrolling of menus, for example.

The invention proposes a mechanism of the type defined in the opening paragraph which provides great ease of handling of this navigation key and is well adapted to mechanisms of small dimensions utilizing rubber keys while largely avoiding multiple contacts.

Such a mechanism is characterized in that a configuration of ribs is provided for separating said contact points.

These and other aspects of the invention are apparent from and will be elucidated, by way of non-limitative example, with reference to the embodiment(s) described hereinafter.

In the drawings:

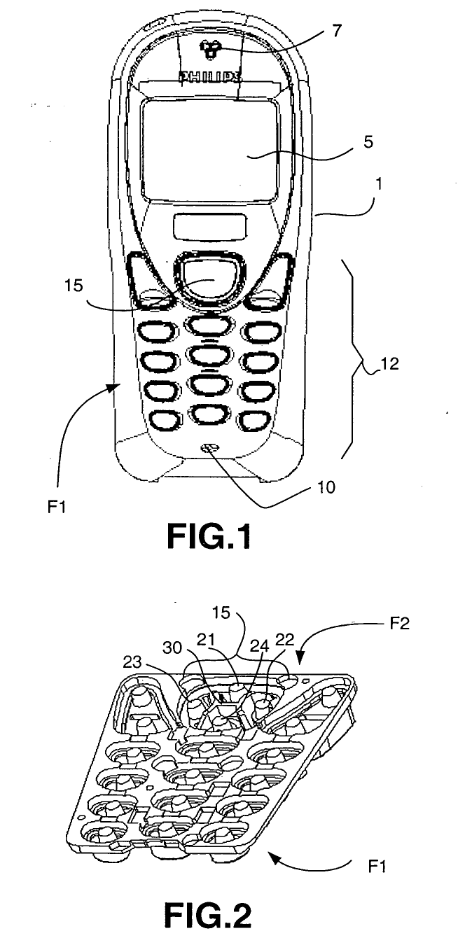

FIG. 1 shows an electronic mechanism in accordance with the invention,

FIG. 2 shows the surface of the keyboard comprising the ribs surrounding the contact points,

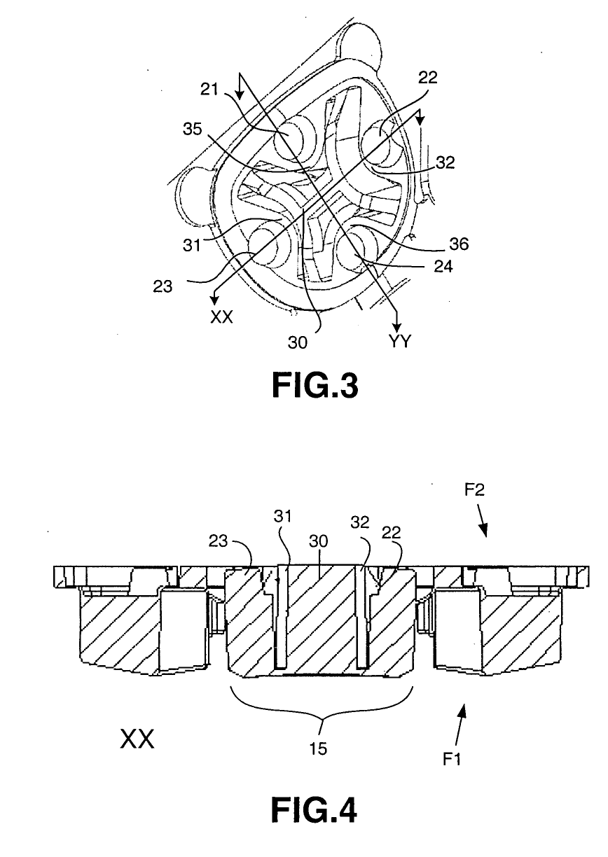

FIG. 3 shows in enlarged manner the navigation key with section lines,

FIG. 4 shows one of said sections,

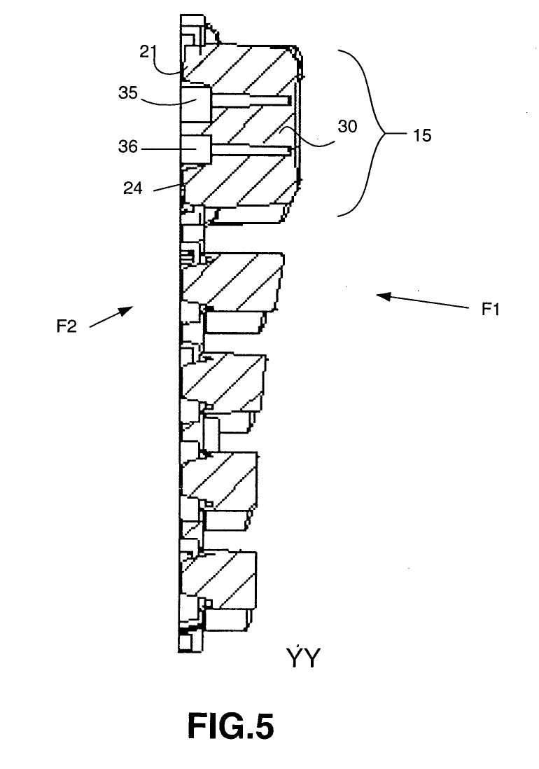

FIG. 5 shows the other of said sections.

In FIG. 1 is shown a mechanism in accordance with the invention. This mechanism is a telephone station adapted to the cellular network, for example. This mechanism comprises a housing 1 on which a screen 5 is provided, a loudspeaker 7, a microphone 10 and a keyboard 12. On this keyboard is distinguished a navigation key 15 arranged on a first face of a membrane F 1. This key may be moved from top to bottom and from right to left, which implies the presence of four contacts for scrolling, for example, the items of a scrolling menu.

These keys are formed on the membrane which has been mentioned. This membrane shown in FIG. 2 is made of a rubber material or a similar material. This FIG. 2 shows in a perspective view the second face of this membrane which bears reference F2. On this face are shown the contact points 21, 22, 23 and 24 which will rest on the contacts provided on the printed circuit (not shown) placed in the housing 1.

According to the invention these contact points are surrounded at least partly by a configuration of ribs 30. These ribs in the example are in the form of an “H” which separates said contact points.

FIG. 3 shows said navigation key 15 in enlarged form. In this Figure are represented by reference 31 the spaces provided between the contact point 23 and the rib 30. Reference 32 shows the space between this rib 30 and the contact point 22. A section line XX passes through these various elements which have just been mentioned: 23, 31, 32 and 22. In similar manner a space 35 has been provided between the contact point 21 and the rib 30 and another rib referred to as 36 between this same rib 30 and the contact point 24. A section line YY runs through the latter elements, that is to say: 21, 35, 36 and 24.

FIG. 4 shows the section XX. This Figure shows the relative dimensions of the contact points 22, 23, the spaces 31 and 32 and also the importance of the rib 30.

FIG. 5 shows the section YY, for example a section of the elements 21, 35, 30, 36 and 24.

1. An electric mechanism comprising a keyboard which includes at least one key called navigation key, showing on one side a surface for the user to depress and on the other side various contact points, characterized in that a configuration of ribs is provided for separating said contact points.

2. An electric mechanism as claimed in claim 1, characterized in that this configuration is shown in the form of an H whose legs surround the contact points.

3. An electric mechanism as claimed in one of the claims 1 to 2, characterized in that the keyboard is formed from a membrane of rubber material.
